(19) United States
(12) Patent Application Publication
(10) Pub. No.: US 2007/0126095 A1
(43) Pub. Date: Jun. 7, 2007

(54) Semiconductor device and manufacturing method thereof

(75) Inventor: Hisashi Tanie, Mito (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 11/607,312

(22) Filed: Nov. 30, 2006

(30) Foreign Application Priority Data
Dec. 2, 2005 (JP) 2005-348638

(51) Int. Cl. H01L 23/495

(52) U.S. Cl. 257/676

(57) ABSTRACT

A semiconductor device has a semiconductor package with a semiconductor element is mounted on a mounting substrate. The mounting substrate has at least two anisotropic areas which are located at both sides of a semiconductor package mounting area in a way to sandwich it and have an anisotropic linear expansion coefficient. In the anisotropic areas, a linear expansion coefficient in a direction toward a center of the semiconductor package mounting area is larger than a linear expansion coefficient in an in-plane direction of the mounting substrate perpendicular to the direction and larger than a linear expansion coefficient of the semiconductor package mounting area in a direction toward the anisotropic areas. The semiconductor device makes it possible to reduce thermal deformation of a semiconductor package mounting area of a mounting substrate easily and at low cost.

### CLAIM OF PRIORITY

The present application claims priority from Japanese application serial No. 2005-348638 filed on Dec. 2, 2005, the content of which is hereby incorporated by reference into this application.

### BACKGROUND OF THE INVENTION

The present invention relates to a semiconductor device and manufacturing method thereof.

A semiconductor device in which a semiconductor package with a semiconductor element is joined to a surface of a mounting substrate has been widely put to practical use. In connection with this type of semiconductor device, it has been known that it is effective to reduce the difference in the amount of thermal deformation between the semiconductor package and the mounting substrate in order to prevent the reliability of the connection between the semiconductor package and the mounting substrate from deteriorating due to temperature change. Japanese Patent Laid-Open No. 2002-335057 discloses a technique which uses a metal material with a small linear expansion coefficient as the core material of the mounting substrate, as a technique of reducing the difference in the amount of thermal deformation between the semiconductor package and the substrate by reducing the amount of thermal deformation of the mounting substrate.

The epoxy resin containing glass fiber which is widely used for mounting substrates has a larger linear expansion coefficient than the silicon as the main material of semiconductor elements. For this reason, if temperature change occurs in a semiconductor device in which a semiconductor package with a semiconductor element is joined onto a mounting substrate, thermal deformation of the mounting substrate would be larger than that of the semiconductor package and this difference in the amount of thermal deformation might cause a strain in the connection between the semiconductor package and the mounting substrate. If the strain in the connection should be large, a defect such as fatigue cracking might occur in the connection; therefore, it is necessary to reduce thermal deformation of the mounting substrate. As one approach to reducing thermal deformation of the mounting substrate, it has been proposed that the material of the mounting substrate is changed to a material with a small linear expansion coefficient as described above in Japanese Patent Laid-Open No. 2002-335057. However, with the technique described in this patent document, the material cost may rise or the use of a new material may cause a manufacturing or management problem.

### SUMMARY OF THE INVENTION

An object of the present invention is to provide a semiconductor device which makes it possible to reduce thermal deformation of a semiconductor package mounting area of amounting substrate easily and at low cost, and a manufacturing method thereof.

In order to achieve the above object, according to a first aspect of the present invention, in a semiconductor device in which a semiconductor package with a semiconductor element is mounted on a mounting substrate, the mounting substrate has at least two anisotropic areas which are located at both sides of a semiconductor package mounting area in a way to sandwich it and have an anisotropic linear expansion coefficient; and in the anisotropic areas, a linear expansion coefficient in a direction toward a center of the semiconductor package mounting area is larger than a linear expansion coefficient in an in-plane direction of the mounting substrate perpendicular to the direction and larger than a linear expansion coefficient of the semiconductor package mounting area in a direction toward the anisotropic areas.

According to the first aspect of the invention, a preferred embodiment is characterized as follows:

(1) Resin containing glass fiber is used as a material of the mounting substrate and the length of glass fiber of the anisotropic areas in a direction toward the semiconductor package mounting area is shorter than the length of glass fiber in a direction intersecting with the direction.

(2) Resin containing glass fiber is used as a material of the mounting substrate and the amount of glass fiber of the anisotropic areas in a direction toward the semiconductor package mounting area is smaller than the amount of glass fiber in a direction intersecting with the direction.

(3) An edge of each of the anisotropic areas nearer to the semiconductor package mounting area is longer at both its ends than an edge of the semiconductor package mounting area opposite to it.

(4) The anisotropic areas are two pairs located fore and aft and left and right of the semiconductor package mounting area and arranged to surround the semiconductor package mounting area.

(5) In addition to (4), an edge of each of the anisotropic areas nearer to the semiconductor package mounting area is almost as long as an edge of the semiconductor package mounting area opposite to it and its farther edge is longer than the nearer edge.

(6) A plurality of the semiconductor package mounting areas are located side by side and the anisotropic areas are areas between neighboring ones of these semiconductor package mounting areas.

According to a second aspect of the invention, in a method of manufacturing a semiconductor device in which a semiconductor package with a semiconductor element is joined to, and mounted on, a mounting substrate, at least two anisotropic areas are made in a way to sandwich a semiconductor package mounting area of the mounting substrate, where a linear expansion coefficient of the anisotropic areas in a direction toward a center of the semiconductor package mounting area is larger than a linear expansion coefficient in an in-plane direction of the mounting substrate perpendicular to the direction and larger than a linear expansion coefficient of the semiconductor package mounting area in a direction toward the anisotropic areas; and subsequently the semiconductor package is joined onto the semiconductor package mounting area of the mounting substrate.

According to the second aspect of the invention, a preferred embodiment is characterized as follows:

(1) The mounting substrate is produced by stacking a plurality of prepregs made of resin containing glass fiber.

(2) In addition to the above (1), in at least one of the plural prepregs, a cut is made so that the length of glass fiber in a direction toward the semiconductor package mounting area is shorter than the length of glass fiber in a direction toward intersecting with the direction and then the plural prepregs are stacked and hot-cured to make the cut glass fiber area the anisotropic area.

(3) The plural prepregs are made from epoxy resin containing a glass fiber sheet having glass fibers oriented in two orthogonal directions and a cut is made in the glass fiber sheet along any of the glass fiber orthogonal directions in at least one of the plural prepregs to shorten the length of the glass fiber in one direction, and then the plural prepregs are stacked and hot-cured to make the cut glass fiber area the anisotropic area.

(4) The plural prepregs are made from resin containing glass fiber oriented in one direction and after cutting off portions corresponding to the anisotropic areas in at least one of the prepregs, the anisotropic areas are made by stacking the prepregs in a way that the glass fibers are oriented in different directions.

Therefore, the semiconductor device and the method of manufacturing the same according to the present invention make it possible to reduce thermal deformation of a semiconductor package mounting area of a mounting substrate easily and at low cost.

### BRIEF DESCRIPTION OF THE DRAWINGS

The invention will be more particularly described with reference to the accompanying drawings, in which:

FIG. 1 illustrates a semiconductor device according to a first embodiment of the present invention;

FIGS. 2(a) and 2(b) illustrate the difference between a mounting substrate used in the first embodiment of the invention and a commonly used glass epoxy resin substrate, in which FIG. 2(a) concerns the commonly used glass epoxy resin substrate and FIG. 2(b) concerns the substrate in the invention;

FIG. 3 is a schematic view showing different linear expansion coefficients in different areas of the mounting substrate shown in FIG. 1;

FIGS. 4(a) and 4(b) show stress distributions upon temperature rise in the mounting substrate shown in FIG. 1, in which FIG. 4(a) shows stress distribution in the x direction and FIG. 4(b) shows stress distribution in the y direction;

FIGS. 5(a) and 5(b) show distributions of strain (apparent linear expansion coefficient) which occurs when the temperature rises, in which FIG. 5(a) shows an apparent thermal expansion coefficient in the x direction and FIG. 5(b) shows one in the y direction;

FIG. 6 is a characteristic graph showing the relation between the anisotropic area size and the semiconductor package mounting area's apparent linear coefficient in the mounting substrate shown in FIG. 1;

FIG. 7 illustrates a first method of manufacturing a mounting substrate constituting a semiconductor device in the first embodiment;

FIG. 8 illustrates a second method of manufacturing a mounting substrate constituting a semiconductor device in the first embodiment;

FIGS. 9(a), 9(b) and 9(c) illustrate a third method of manufacturing amounting substrate constituting a semiconductor device in the first embodiment, in which FIG. 9(a) shows a prepreg cutting pattern, FIG. 9(b) shows a second prepreg cutting pattern and FIG. 9(c) shows a third prepreg cutting pattern;

FIGS. 10(a) and 10(b) illustrate a second embodiment of the invention, in which FIG. 10(a) is a plan view and FIG. 10(b) is a side view;

FIG. 11 illustrates a third embodiment of the invention;

FIG. 12 illustrates a fourth embodiment of the invention; and

FIG. 13 illustrates a fifth embodiment of the invention.

### DETAILED DESCRIPTION OF THE PREFERRED EMBODIMENTS

Next, preferred embodiments of the present invention will be described referring to the accompanying drawings. In drawings that illustrate the preferred embodiments, the same or equivalent elements are designated by the same reference numerals.

### First Embodiment

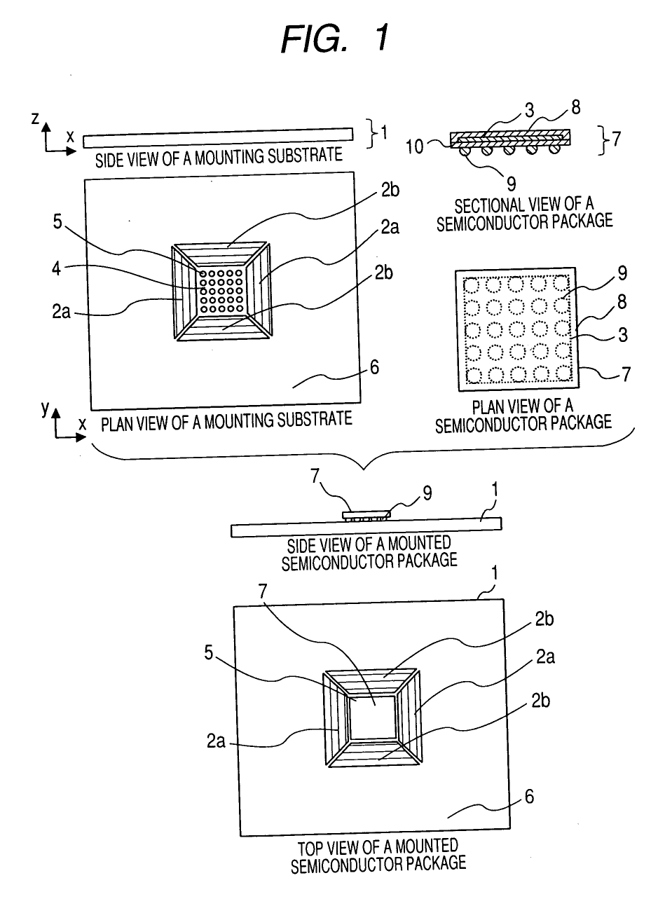

A first embodiment of the present invention will be described referring to FIGS. 1 to 10(b).

FIG. 1 schematically shows a semiconductor device according to the first embodiment. A mounting substrate 1, the main material of which is an epoxy resin containing glass fiber, consists of a laminate including one or more Cu wiring layer. As shown in a plan view of the mounting substrate, a plurality of metal lands 5 for electrical connection with the semiconductor package 7 are provided in a square semiconductor package mounting area 4.

At both sides of the semiconductor package mounting area 4 in its x direction, there are anisotropic areas 2a whose linear expansion coefficient is larger than that of the semiconductor package mounting area 4 in the x direction and equal to that of the semiconductor package mounting area 4 in the y direction. Also, at both sides of the semiconductor package mounting area 4 in its y direction, there are anisotropic areas 2b whose linear expansion coefficient is larger than that of the semiconductor package mounting area 4 in the y direction and equal to that of the semiconductor package mounting area 4 in the x direction. In other words, the anisotropic areas 2a and 2b are two pairs fore and aft and right and cleft of the semiconductor package mounting area 4, in a way to surround the semiconductor package mounting area 4. Each anisotropic area (2a, 2b)'s edge nearer to the semiconductor package mounting area 4 is almost as long as the corresponding edge of the semiconductor package mounting area 4 and its farther edge is longer than the nearer edge so that the anisotropic area is almost trapezoidal. The linear expansion coefficient of an area 6 away from the semiconductor package mounting area 4 is equal to that of the semiconductor package mounting area 4 in both the x and y directions. Here, the x, y, and z directions refer to ordinary geometric directions where the x and y directions represent the in-plane directions of the mounting substrate.

In this embodiment, the semiconductor package 7 mounted on the mounting substrate 1 has a ball grid array structure in which a semiconductor element 3 is connected to the upper surface of a semiconductor package substrate 10 and sealed with mold resin 8 and solder balls 9 are joined to the lower surface of the semiconductor package substrate 10. The semiconductor package 7 and the mounting substrate 1 are electrically connected by joining the solder balls 9 of the semiconductor package 7 and the land 5 on the surface of the mounting substrate 1, enabling the package to work as a semiconductor device. In the figure, the vertical stripes and horizontal stripes in the anisotropic areas 2a and 2b symbolize not glass fiber but the anisotropic areas 2a and 2b.

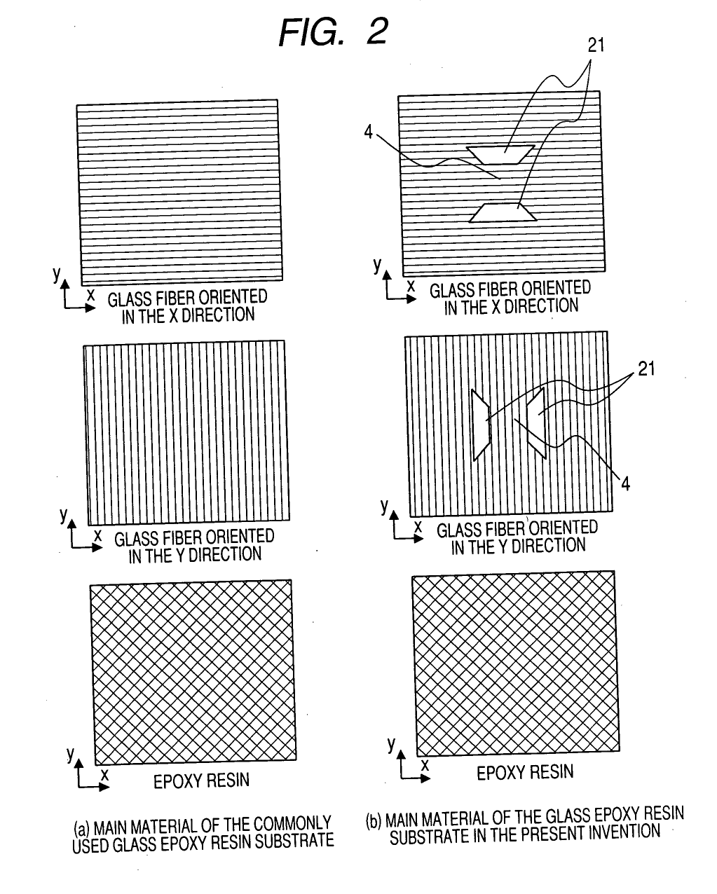

In this embodiment, some areas of the mounting substrate 1 are different from other areas of it in terms of linear expansion coefficient and the areas around the semiconductor package mounting area 4 are anisotropic. FIGS. 2(a) and 2(b) compare the substrate in this embodiment which features such location-dependency of linear expansion coefficient and anisotropy, against the commonly used glass epoxy resin substrate.

FIG. 2(a) visually shows glass fiber oriented in the x direction, glass fiber oriented in the y direction and epoxy resin which constitute a commonly used glass epoxy resin substrate. The commonly used glass epoxy resin substrate is composed of a glass cloth produced by weaving glass fibers oriented in the x and y directions, and epoxy resin which fills the gaps in the glass cloth. Although the actual mounting substrate 1 has wires and via holes, they are omitted here and the features of this embodiment will be explained with attention focused on the glass epoxy resin. The linear expansion coefficient of the glass fiber is smaller than that of the epoxy resin, which means that the linear expansion coefficient of a composite material as a combination of the glass fiber and epoxy resin is smaller in a location or direction in which more glass fiber is contained. However, in the commonly used glass epoxy resin substrate, the glass fiber orientation is not location- or direction-dependent and thus the linear expansion coefficient does not depend on location or direction and variability is uniform.

On the other hand, the glass epoxy resin substrate in this embodiment as shown in FIG. 2(b), the x-oriented glass fiber at both sides of the semiconductor package mounting area 4 in the y direction are removed to leave areas free of glass fiber. Similarly, the y-oriented glass fiber at both sides of the semiconductor package mounting area 4 in the x direction are removed. The gaps in the glass cloth woven with glass fiber including such fiber-free areas are filled with epoxy resin to constitute a glass epoxy resin substrate. Vacancy formation inside the mounting substrate 1 can be prevented by filling epoxy resin in glass fiber-free areas in this way. In the anisotropic areas 2a and 2b thus created, the amount of glass fiber oriented toward the semiconductor package mounting area 4 is smaller than the amount of glass fiber in a direction intersecting with that direction.

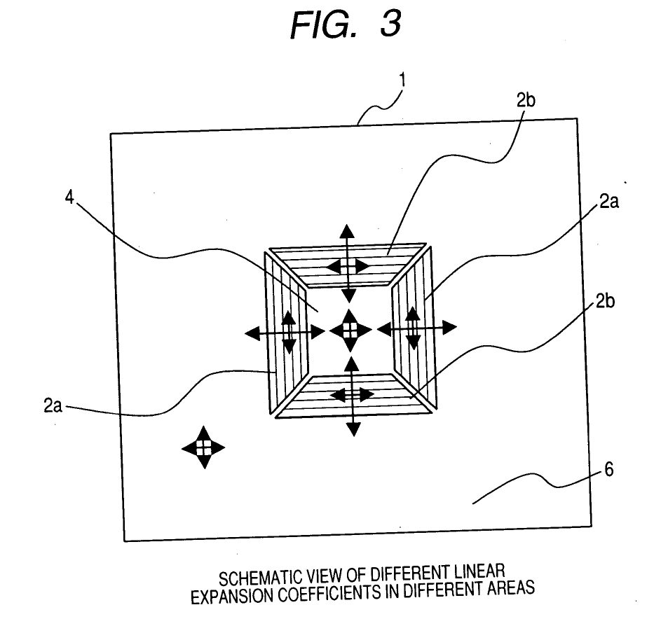

FIG. 3 schematically shows different linear expansion coefficients in the areas 4, 2a, 2b and 6 of the mounting substrate 1 with the glass fiber profile as shown in FIG. 2(b). Since the semiconductor package mounting area 4 and the area 6 away from the semiconductor package mounting area 4 (namely, areas except the anisotropic areas 2a and 2b) have glass fiber in both the x and y directions, the linear expansion coefficient of the mounting substrate 1 is equal to that of the commonly used glass epoxy resin substrate as shown in FIG. 2(a). On the other hand, the anisotropic areas 2a exist at both sides of the semiconductor package mounting area 4 in the x direction where these areas have glass fiber in the y direction only and do not have glass fiber in the x direction. In these anisotropic areas 2a, the linear expansion coefficient in the y direction is equal to that of the commonly used glass epoxy resin substrate because the areas have glass fiber in the same way as the glass epoxy resin substrate, while in the x direction, because of the absence of glass fiber, they have a larger linear expansion coefficient and their modulus of elasticity (Young's modulus) becomes smaller. Similarly, the anisotropic areas 2b exist at both sides of the semiconductor package mounting area 4 in the y direction where these areas have glass fiber in the x direction only and do not have glass fiber in the y direction. In these anisotropic areas 2b, the linear expansion coefficient in the x direction is equal to that of the commonly used glass epoxy resin substrate, while in they direction they have a larger linear expansion coefficient and their Young's modulus becomes smaller.

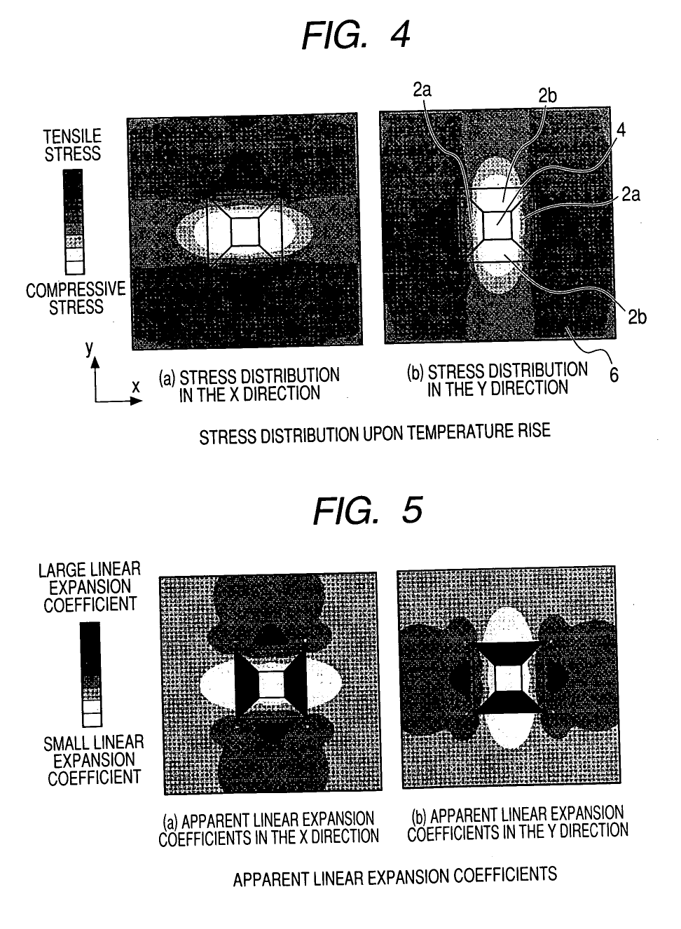

Next, a mechanism to reduce thermal deformation of the semiconductor package mounting area 4 according to this embodiment will be explained referring to FIGS. 4(a) and 4(b) and FIGS. 5(a) and 5(b).

FIGS. 4(a) and 4(b) show stress distributions as seen in the mounting substrate 1 as the temperature of the mounting substrates 1 rises.

FIG. 4(a) shows vertical stress distribution in the x direction. Compressive stress is generated in the semiconductor package mounting area 4. The mechanism of compressive stress generation is as follows. As the temperature rises, various parts of the mounting substrate 1 expand with heat. At this time, the anisotropic areas 2a around the semiconductor package mounting area 4 in the x direction try to expand more in the x direction because their linear expansion coefficient is larger than the linear expansion coefficient of the semiconductor package mounting area 4 and the area 6 away from the semiconductor package mounting area 4 in the x direction. However, since they are surrounded by the material which constitutes the semiconductor package mounting area 4 and the area 6 away from the semiconductor package mounting area 4, they cannot expand with heat freely; instead the anisotropic areas 2a push their adjacent area (namely the semiconductor package mounting area 4) toward the x direction. As a consequence, the semiconductor package mounting area 4 is pushed from both left and right and compressive stresses are thus generated. These compressive stresses partially cancel thermal expansion of the semiconductor package mounting area 4, resulting in reduction of thermal deformation of the semiconductor package mounting area 4.

On the other hand, as the temperature goes down, tensile stresses are generated in the semiconductor package mounting area 4 by a mechanism opposite to the mechanism which occurs upon temperature rise, which partially cancels thermal contraction and thus reduces thermal deformation of the semiconductor package mounting area 4.

FIGS. 5(a) and 5(b) show strain distributions as seen when the temperature rises by 1° C. If the material is homogeneous, the value here should be equal to the linear expansion coefficient of the material and therefore this value is hereinafter referred to as the “apparent linear expansion coefficient.”

FIG. 5(a) shows apparent linear expansion coefficients in the x direction. The apparent linear expansion coefficient of the semiconductor package mounting area 4 is smaller than the apparent linear expansion coefficient of the area 6 which is considered to be less affected by the anisotropic areas. This is because, when the temperature rises, the semiconductor package mounting area 4 is compressed and its thermal expansion becomes smaller. It is demonstrated here that the apparent linear expansion coefficient of the semiconductor package mounting area 4 decreases according to this embodiment. By contrast, the apparent linear expansion coefficient of the anisotropic areas 2a around the semiconductor package mounting area 4 is very large. This is because in these areas, the linear expansion coefficient in the x direction is very large because of absence of glass fiber in the x direction. However, it is the apparent linear expansion coefficient of the semiconductor package mounting area 4 that governs the reliability of the connection between the semiconductor package 7 and the mounting substrate 1 and even when the apparent linear expansion coefficient of the area on which the semiconductor package is not mounted is large, the reliability of the connection is not affected and no reliability problem will arise. FIG. 5(b) shows apparent linear expansion coefficients in the y direction. As in the x direction, it can be confirmed from the figure that the apparent linear expansion coefficient of the semiconductor package mounting area 4 decreases.

For the above reason, the apparent linear expansion coefficients of the semiconductor package mounting area 4 decrease in both the x and y directions so that the reliability of the connection between the semiconductor package 7 and the mounting substrate 1 is improved.

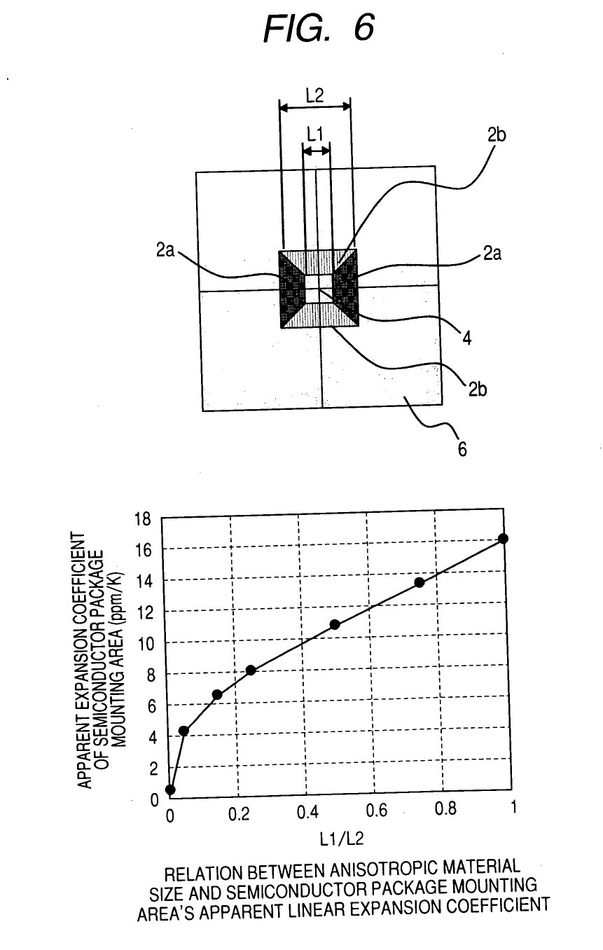

FIG. 6 quantitatively shows the effect of this embodiment. The effect of this embodiment varies with the size of the semiconductor package mounting area 4 and the size of the anisotropic areas 2a and 2b. Here, let the size of the semiconductor package mounting area 4 be defined as L1 and the distance between the outer edges of the anisotropic areas 2a be defined as L2. The graph of FIG. 6 shows change in the apparent linear expansion coefficient of the semiconductor package mounting area 4 when the ratio of L1 to L2 is changed. In the test for obtaining this data, the value of L2 was fixed and the value of L1 was changed to confirm the effect. Regarding physical properties of the materials, the isotropic glass epoxy resin substrate data was used for the direction which involves glass fiber and the epoxy resin data was used for the direction which does not involve glass fiber. Hence in the direction involving glass fiber, the linear expansion coefficient is larger and Young's modulus is smaller than in the direction not involving glass fiber.

In the graph of FIG. 6, L1/L2=1 means that the anisotropic areas 2a and 2b do not exist, namely the substrate is an isotropic glass epoxy resin substrate to which the present invention is not applied. While the apparent linear expansion coefficient of the semiconductor package mounting area 4 of the isotropic glass epoxy resin substrate is 16 ppm/K (which agrees with the linear expansion coefficient of the material itself because it is isotropic), the apparent linear expansion coefficient of the semiconductor package mounting area 4 decreases as the value of L1/L2 becomes smaller; for example, when L1/L2=⅓ (in this case the size of the semiconductor package mounting area 4 is equal to the size of each of the anisotropic areas 2a), the apparent linear expansion coefficient is 8 ppm/K, a half of that of the substrate to which the present invention is not applied. From this it can be known that it is possible to make the apparent linear expansion coefficient smaller than the linear expansion coefficient of silicon as the main material of the semiconductor element by decreasing the value of L/L2 further.

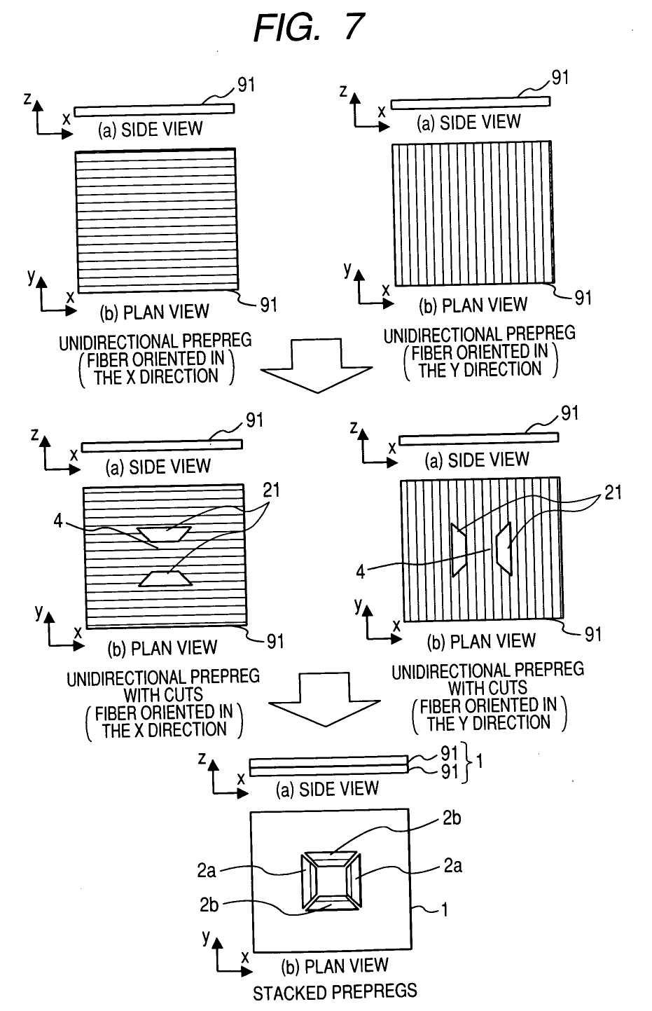

Next, a first method of manufacturing a semiconductor device according to this embodiment will be described referring to FIG. 7.

In the first manufacturing method, a plurality of unidirectional prepregs 91, which are prepared by half-curing epoxy resin containing glass fiber oriented in one direction, are used to produce a mounting substrate 1 according to this embodiment. First, a unidirectional prepreg 91 with glass fiber oriented only in the x direction and a unidirectional prepreg 91 with glass fiber oriented only in they direction are prepared.

Next, areas 21 at both sides in they direction of a semiconductor package mounting area 4 of the unidirectional prepreg 91 with glass fiber oriented only in the x direction and areas 21 at both sides in the x direction of a semiconductor package mounting area 4 of the unidirectional prepreg 91 with glass fiber oriented only in the y direction are removed. Then, these two prepregs 91 are stacked one upon the other. The epoxy resin contained in the prepregs 91 is hot-cured to produce a mounting substrate 1 having anisotropic areas 2a and 2b according to this embodiment.

Although not only the glass fiber but also the epoxy resin are removed during the process of removing areas of the unidirectional prepregs 91 around the semiconductor package mounting area 4 in the first manufacturing method, even removal or reduction of only the glass fiber can bring about the same effect of the present invention. In the first embodiment, two prepregs 91 are stacked; however more than two prepregs 91 may be stacked and in that case, the anisotropy of the material in its thickness direction becomes smaller and warping of the mounting substrate is reduced.

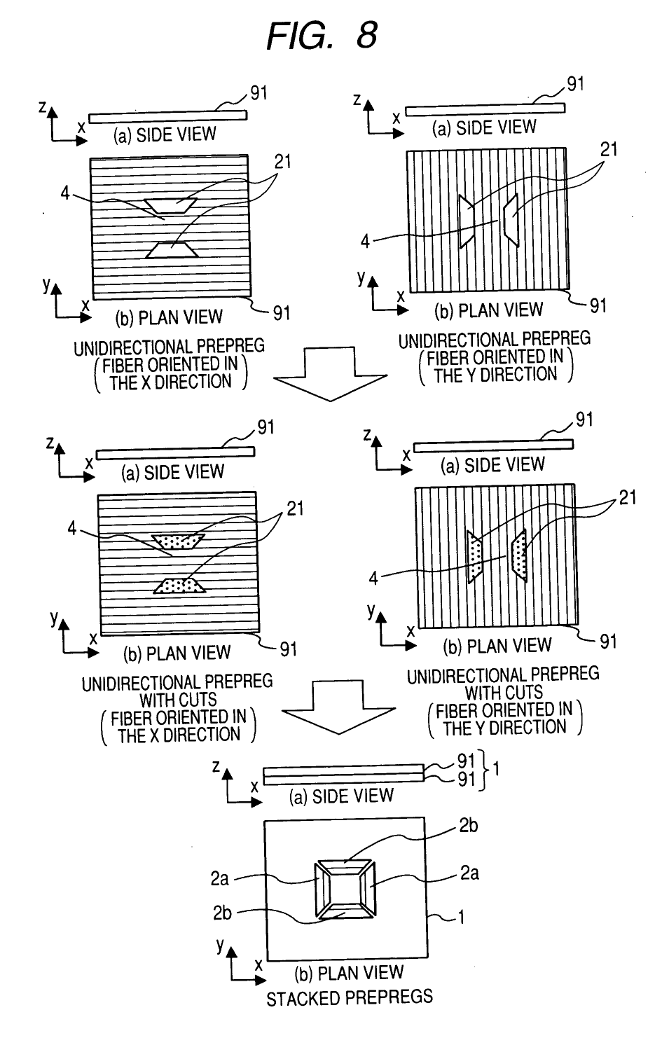

Next, a second method of manufacturing a semiconductor device according to this embodiment will be described referring to FIG. 8.

In this second manufacturing method, like in the first, a plurality of unidirectional prepregs 91, which are prepared by half-curing epoxy resin containing glass fiber oriented in one direction, are used to produce a mounting substrate according to this embodiment. It is the same as the first manufacturing method in that at the first step, areas 21 at both sides in the y direction of a semiconductor package mounting area 4 of a unidirectional prepreg 91 with glass fiber oriented only in the x direction and areas 21 at both sides in the x direction of a semiconductor package mounting area 4 of a unidirectional prepreg 91 with glass fiber oriented only in the y direction are removed. The difference from the first manufacturing method is that the vacant spaces corresponding to the removed areas 21 are filled with filler resin 81 which has the same shape as the removed areas 21. In the second manufacturing method, large vacant spaces are not generated inside the stacked prepregs 91, which makes it easier to prevent generation of voids in the epoxy resin hot-curing process. Furthermore, if the filler resin 81 contains glass fiber oriented perpendicularly to the removed glass fiber, the effect of the present invention is larger.

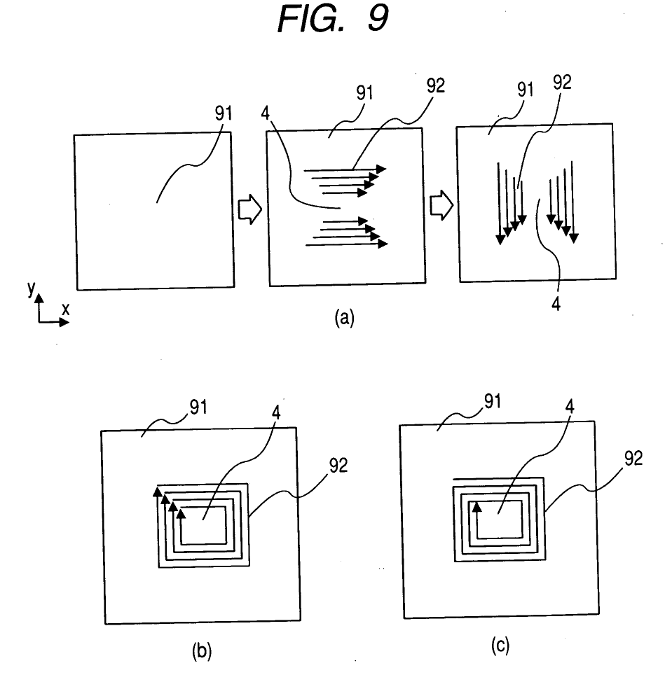

Next, a third method of manufacturing a semiconductor device according to this embodiment will be described referring to FIGS. 9(a) to 9(c).

In the third manufacturing method, first a prepreg 91 is prepared by half-curing epoxy resin containing glass cloth woven with glass fibers oriented in the x and y directions perpendicularly to each other. Next, areas of the prepreg 91 at both sides in the y direction of the semiconductor package mounting area 4 are cut along the x direction several times using a laser as indicated by cutting lines 92. Another cutting means may be used if it is able to cut the glass fiber.

As a result of cutting the prepreg 91 along the x direction in this way, the fiber oriented in the y direction is cut into short pieces and the effect of suppressing thermal deformation of the prepreg 91 decreases, so that the linear expansion coefficient of these areas of the prepreg 91 in the y direction becomes larger. On the other hand, the glass fiber oriented in the x direction is not cut and the linear expansion coefficient of these areas of the prepreg 91 in the x direction does not become larger. Consequently, the prepreg 91 in these surrounding areas in which cuts have been made becomes anisotropic in terms of linear expansion coefficient. Next, areas of the prepreg 91 at both sides in the x direction of the semiconductor package mounting area 4 are cut along the y direction several times. As a result of cutting the prepreg 91 in this way, the linear expansion coefficient of these areas of the prepreg 91 in the x direction becomes larger by a mechanism similar to the abovementioned. Then the epoxy resin is hot-cured to finish a mounting substrate 1. At this time, since the fluidity of the uncured epoxy resin increases upon temperature rise, the epoxy resin flows into the cuts made in the prepreg 91, thereby preventing generation of voids in the mounting substrate 1.

Alternatively, even if cuts may be made in the prepreg 91 as indicated in FIGS. 9(b) and 9(c), a similar effect can be achieved. In order to make cuts as indicated in FIGS. 9(b) and 9(c), cutting directions must be changed but the number of cuts is decreased.

### Second Embodiment

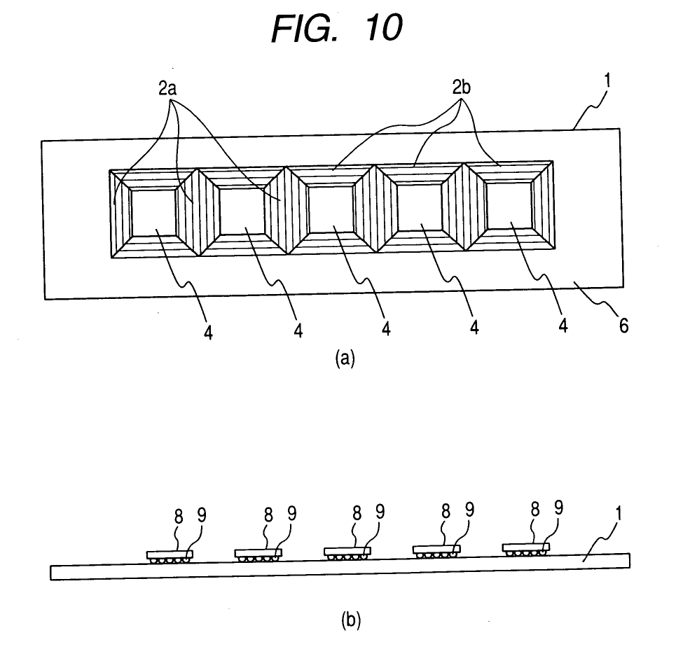

Next, a second embodiment of the present invention will be described referring to FIGS. 10(a) and 10(b). FIGS. 10(a) and 10(b) show a semiconductor device according to the second embodiment of the invention, in which FIG. 10(a) is a schematic plan view of a mounting substrate of the semiconductor device according to the second embodiment and FIG. 10(b) is a side view of the semiconductor device according to the second embodiment. The second embodiment is different from the first embodiment in the aspect described below but other aspects are basically the same as in the first embodiment and repeated descriptions thereof are omitted.

In the second embodiment, a plurality of semiconductor packages 7 are mounted on a single mounting substrate 1. The second embodiment is characterized in that anisotropic areas 2a with a large linear expansion coefficient in the x direction and anisotropic areas 2b with a large linear expansion coefficient in the y direction are located around each semiconductor package mounting area 4 and a plurality of such anisotropic areas are provided in a way to surround the semiconductor package mounting areas 4.

According to the second embodiment, a plurality of semiconductor packages 7 can be mounted and greater design freedom is ensured by using semiconductor package mounting areas 4 as desired for mounting semiconductor packages 7. The anisotropic areas 2a between semiconductor package mounting areas 4 have large linear expansion coefficients which counteract the semiconductor package mounting areas 4 at both sides of them, so that thermal deformation of the semiconductor package mounting areas can be reduced effectively in a compact manner.

### Third Embodiment

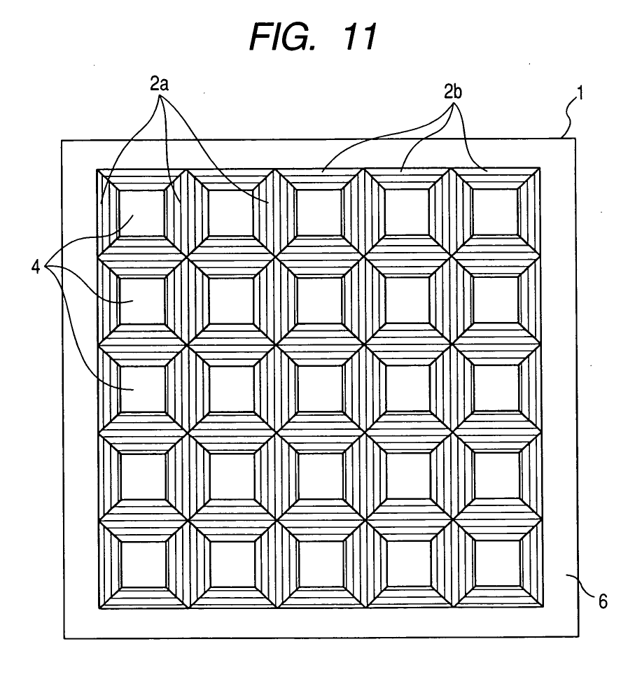

Next, a third embodiment of the present invention will be described referring to FIG. 11. FIG. 11 is a schematic plan view of a mounting substrate used in a semiconductor device according to the third embodiment of the invention. The third embodiment is different from the second embodiment in the aspect described below but other aspects are basically the same as in the second embodiment and repeated descriptions thereof are omitted.

In the third embodiment, many anisotropic areas 2a and 2b are arranged in a grid pattern on a single mounting substrate where the anisotropic areas 2a have a large linear expansion coefficient in the x direction and the anisotropic areas 2b have a large linear expansion coefficient in the y direction. In this embodiment, thermal deformation is small in many areas of the mounting substrate and thus the positions and number of semiconductor packages 7 to be mounted on the mounting substrate can be relatively freely selected. Therefore, it is easy to design the substrate taking electrical properties and wire interconnections into consideration.

### Fourth Embodiment

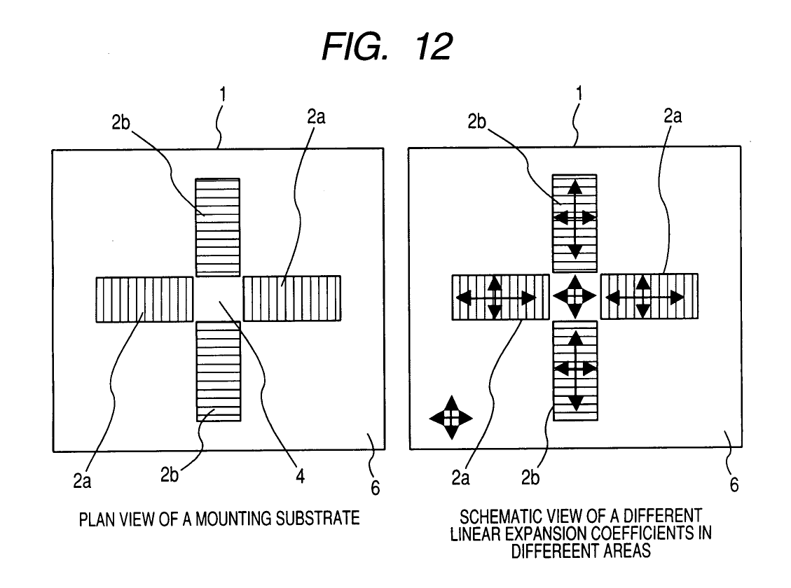

Next, a fourth embodiment of the present invention will be described referring to FIG. 12. FIG. 12 is a schematic plan view of a mounting substrate used in a semiconductor device according to the fourth embodiment of the invention. The fourth embodiment is different from the first embodiment in the aspect described below but other aspects are basically the same as in the first embodiment and repeated descriptions thereof are omitted.

The fourth embodiment is characterized in that anisotropic areas 2a and 2b of a mounting substrate are rectangular where the anisotropic areas 2a have a large linear expansion coefficient in the x direction and the anisotropic areas 2b have a large linear expansion coefficient in they direction. In this fourth embodiment, since the anisotropic areas 2a and 2b are rectangular, removal of the relevant areas of prepregs 91 in the manufacturing process can be performed simply by cutting only in the x and y directions and also the effect of the anisotropic areas 2a and 2b on the semiconductor package mounting area 4 is increased. However, in the vicinity of each corner of the semiconductor package mounting area, the pushing force of the anisotropic material upon temperature rise and its tensile load upon temperature drop are smaller than in the first embodiment and thus the effect of reducing thermal deformation of the semiconductor package mounting area is smaller than in the first embodiment.

### Fifth Embodiment

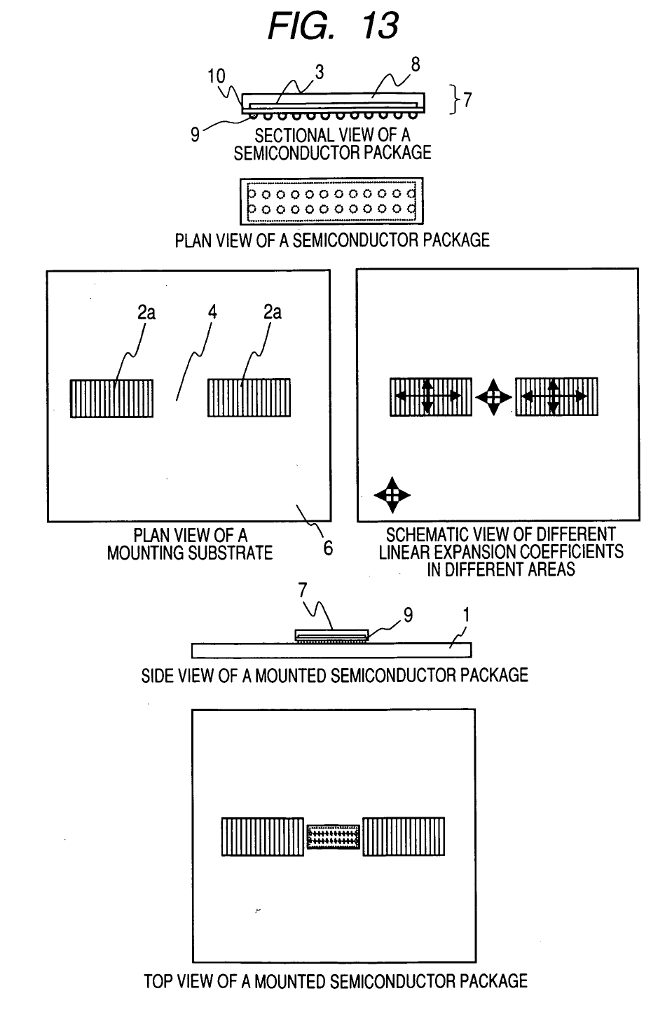

Next, a fifth embodiment of the present invention will be described referring to FIG. 13. FIG. 13 illustrates a semiconductor device according to the fifth embodiment of the invention. The fifth embodiment is different from the fourth embodiment in the aspect described below but other aspects are basically the same as in the fourth embodiment and repeated descriptions thereof are omitted.

In the fifth embodiment, a mounting substrate 1 has no anisotropic areas 2b with a large linear expansion coefficient in the y direction but only has a plurality of anisotropic areas 2a with a large linear expansion coefficient in the x direction. In the fifth embodiment, the ratio of the longer edge length to the shorter edge length of a semiconductor package 7 to be mounted on the mounting substrate 1 is large. For this type of semiconductor package 7, the difference in the amount of thermal deformation between the semiconductor package 7 and the mounting substrate 1 in the semiconductor package shorter edge direction less affects the reliability of their connection and rather the reliability of the connection is primarily governed by the difference in the amount of thermal deformation between the semiconductor package 7 and the mounting substrate 1 in the semiconductor package longer edge direction. Hence, when the mounting substrate 1 has only anisotropic areas 2a with a large linear expansion coefficient in the x direction to reduce thermal deformation of the semiconductor package mounting area 4 only in the x direction and the semiconductor package is so located on the mounting substrate as to make the semiconductor package longer edge direction coincide with the x direction, the reliability of the connection is improved. In this case, the anisotropic areas 2a each has an edge extending fore and aft and longer than the edge of the semiconductor package mounting area 4 opposite to it and thus the amount of thermal deformation of the corners of the semiconductor package mounting area 4, which are most likely to deform with heat, can be reduced with reliability.

The invention has been so far explained concretely in reference to preferred embodiments thereof. However, the invention is not limited thereto and it is obvious that these details may be modified in various ways without departing from the spirit and scope thereof.

What is claimed is:

1. A semiconductor device in which a semiconductor package with a semiconductor element is mounted on a mounting substrate,
wherein the mounting substrate has at least two anisotropic areas which are located at both sides of a semiconductor package mounting area in a way to sandwich it and have an anisotropic linear expansion coefficient; and
wherein in the anisotropic areas, a linear expansion coefficient in a direction toward a center of the semiconductor package mounting area is larger than a linear expansion coefficient in an in-plane direction of the mounting substrate perpendicular to the direction and larger than a linear expansion coefficient of the semiconductor package mounting area in a direction toward the anisotropic areas.

2. The semiconductor device according to claim 1, wherein resin containing glass fiber is used as a material of the mounting substrate and the length of glass fiber of the anisotropic areas in a direction toward the semiconductor package mounting area is shorter than the length of glass fiber in a direction intersecting with the direction.

3. The semiconductor device according to claim 1, wherein resin containing glass fiber is used as a material of the mounting substrate and the amount of glass fiber of the anisotropic areas in a direction toward the semiconductor package mounting area is smaller than the amount of glass fiber in a direction intersecting with the direction.

4. The semiconductor device according to claim 1, wherein an edge of each of the anisotropic areas nearer to the semiconductor package mounting area is longer at both its ends than an edge of the semiconductor package mounting area opposite to it.

5. The semiconductor device according to claim 1, wherein the anisotropic areas are two pairs located fore and aft and left and right of the semiconductor package mounting area and arranged to surround the semiconductor package mounting area.

6. The semiconductor device according to claim 5, wherein an edge of each of the anisotropic areas nearer to the semiconductor package mounting area is almost as long as an edge of the semiconductor package mounting area opposite to it and its farther edge is longer than the nearer edge.

7. The semiconductor device according to claim 1, wherein a plurality of the semiconductor package mounting areas are located side by side and the anisotropic areas are areas between neighboring ones of these semiconductor package mounting areas.

8. A method of manufacturing a semiconductor device in which a semiconductor package with a semiconductor element is joined to, and mounted on, a mounting substrate, comprising the steps of:
making at least two anisotropic areas in a way to sandwich a semiconductor package mounting area of the mounting substrate, with a linear expansion coefficient of the anisotropic areas in a direction toward a center of the semiconductor package mounting area being larger than a linear expansion coefficient in an in-plane direction of the mounting substrate perpendicular to the direction and larger than a linear expansion coefficient of the semiconductor package mounting area in a direction toward the anisotropic areas; and
subsequently joining the semiconductor package onto the semiconductor package mounting area of the mounting substrate.

9. The semiconductor device manufacturing method according to claim 8, wherein the mounting substrate is produced by stacking a plurality of prepregs made of resin containing glass fiber.

10. The semiconductor device manufacturing method according to claim 9, wherein in at least one of the plurality of prepregs, a cut is made so that the length of glass fiber in a direction toward the semiconductor package mounting area is shorter than the length of glass fiber in a direction intersecting with the direction and then the plurality of prepregs are stacked and hot-cured to make the cut glass fiber area the anisotropic area.

11. The semiconductor device manufacturing method according to claim 9, wherein the plurality of prepregs are made from epoxy resin containing a glass fiber sheet having glass fibers oriented in two orthogonal directions and a cut is made in the glass fiber sheet along any of the glass fiber orthogonal directions in at least one of the plurality of prepregs to shorten the length of the glass fiber in one direction, and then the plurality of prepregs are stacked and hot-cured to make the cut glass fiber area the anisotropic area.

12. The semiconductor device manufacturing method according to claim 9, wherein the plurality of prepregs are made from resin containing glass fiber oriented in one direction and after cutting off portions corresponding to the anisotropic areas in at least one of the prepregs, the anisotropic areas are made by stacking the prepregs in away that the glass fibers are oriented in different directions.
